(19) United States
(12) Patent Application Publication
(10) Pub. No.: US 2025/0280660 A1
(43) Pub. Date: Sep. 4, 2025

(54) DISPLAY APPARATUS

(71) Applicant: LG Display Co., Ltd., Seoul (KR)

(72) Inventors: SeongHan HWANG, Goyang si (KR); SeungBum LEE, Gimpo-si (KR); KyungKook JANG, Goyang-si (KR)

(73) Assignee: LG Display Co., Ltd., Seoul (KR)

(21) Appl. No.: 18/677,280

(22) Filed: May 29, 2024

(30) Foreign Application Priority Data
Feb. 29, 2024 (KR) 10-2024-0029694

(51) Int. Cl. H10K 59/122; H10K 59/40; H10K 59/80

(52) U.S. Cl. CPC H10K 59/122; H10K 59/8792; H10K 59/40

(57) ABSTRACT

The display apparatus according to an exemplary embodiment of the present disclosure includes: a substrate including a first sub pixel and a second sub pixel; a first electrode disposed in each of the first sub pixel and the second sub pixel; and a bank disposed to cover an end point of the first electrode and separating an emission area and a non-emission area which encloses the emission area, wherein the bank includes a first bank disposed on the first electrode, and a second bank disposed on the first bank and including a trench.

### CROSS-REFERENCE TO RELATED APPLICATIONS

This application claims the priority of Korean Patent Application No. 10-2024-0029694 filed on Feb. 29, 2024, in the Korean Intellectual Property Office, the disclosure of which is incorporated herein by reference.

### BACKGROUND

### Technical Field

The present disclosure relates to a display apparatus, and more particularly, to a display apparatus having a structure for suppressing a leakage current between adjacent sub pixels.

### Discussion of the Related Art

A recent display apparatus, which is capable of displaying various information and can interact with a user who sees the information, needs to have various sizes, various shapes, and various functions.

Examples of the display apparatus include a liquid crystal display (LCD) device, an electrophoretic display device (FPD), a light emitting diode display (LED) device, and the like.

The display apparatus is a self-emitting display apparatus so that a separate light source is not necessary unlike the LCD. Therefore, the display apparatus may be manufactured to have light weight and reduced thickness. Since the display apparatus is driven at a low voltage, it is advantageous not only in terms of power consumption, but also in terms of color implementation, a response speed, a viewing angle, a contrast ratio (CR). Therefore, it is being studied as next generation displays.

Hereinafter, even though the description will be made under the assumption that the display apparatus is an organic light emitting diode display apparatus, the type of the light emitting diode layer is not limited thereto.

The display apparatus displays information on a screen by emitting light from a plurality of pixels including a light emitting diode layer having an emitting layer. The display apparatus can be classified into an active matrix type light emitting diode display apparatus or a passive matrix type light emitting diode display apparatus depending on a method of driving a pixel.

The active matrix type light emitting diode display apparatus controls a current flowing in a light emitting diode using a thin film transistor (TFT) to display images.

The display apparatus includes an anode, an emitting layer, and a cathode. When a voltage is applied to each of the anode and the cathode, holes from the anode and electrons from the cathode are transported to the emitting layer, respectively. When the holes and the electrons are recombined in the emitting layer, excitons are generated and light is emitted by energy from the excitons.

Such a display apparatus is being developed to increase the resolution thereof in order to provide image information of high quality. As the resolution increases, a separation distance between sub pixels decreases. In this case, image information can be distorted by a lateral leakage current between neighboring pixels.

Consequently, various reviews have been performed to suppress a lateral leakage current (LLC) and thus implement a high resolution display apparatus. However, it is still insufficient so that development thereof is urgently required.

### SUMMARY

Accordingly, embodiments of the present disclosure are directed to a display apparatus that substantially obviates one or more of the problems due to limitations and disadvantages of the related art.

An aspect of the present disclosure is to provide a display apparatus which includes a first bank and a second bank disposed on the first bank and including a trench. This is to block a lateral leakage current which increases as a distance between neighboring sub pixels decreases and thus to improve a color reproduction rate.

Another aspect of the present disclosure is to provide a light emitting diode display apparatus in which a light emitting diode layer is disposed on a bank and comprises a curve. This is to increase a transport distance of electrons to neighboring sub pixels and thus to suppress the transport of electrons generated in the light emitting diode layer to the neighboring pixels when the display apparatus is driven.

Yet another aspect of the present disclosure is to provide a light emitting diode display apparatus including a plurality of bank structures. This is to suppress deterioration caused by permeation of ions resulting from foreign matters or particles generated from the display apparatus including a bank containing a black pigment.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises: a substrate including a first sub pixel and a second sub pixel; a first electrode disposed in each of the first sub pixel and the second sub pixel; and a bank disposed to cover an end point of the first electrode and separating an emission area and a non-emission area which encloses the emission area, wherein the bank includes a first bank disposed on the first electrode, and a second bank disposed on the first bank and including a trench.

The display apparatus according to an exemplary embodiment of the present disclosure includes a first bank and a second bank disposed on the first bank and including a trench. Therefore, it is possible to block a lateral leakage current which increases as a distance between neighboring sub pixels decreases and thus to improve a color reproduction rate.

In the display apparatus according to an exemplary embodiment of the present disclosure, a light emitting diode layer is disposed along a curve formed on a bank. Therefore, it is possible to increase a transport distance of electrons to neighboring sub pixels and thus to suppress the transport of electrons generated in the light emitting diode layer to the neighboring pixels when the display apparatus is driven.

The display apparatus according to an exemplary embodiment of the present disclosure includes a plurality of bank structures. Therefore, it is possible to suppress deterioration caused by permeation of ions resulting from foreign matters or particles generated from the display apparatus including a bank containing a black pigment.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view of a display apparatus according to an exemplary embodiment of the present disclosure;

FIG. 2 illustrates the disposition of an emission area and a non-emission area of the display apparatus according to an exemplary embodiment of the present disclosure;

FIG. 3 is a cross-sectional view taken along the line I-I′ of FIG. 2;

FIG. 4 is a cross-sectional view of an emitting unit of the display apparatus according to an exemplary embodiment of the present disclosure;

FIG. 5 illustrates the disposition of an emission area and a non-emission area of the display apparatus according to another exemplary embodiment of the present disclosure; and

FIG. 6 is a cross-sectional view taken along the line II-II′ of FIG. 5.

### DETAILED DESCRIPTION

The advantages and features of the present disclosure, and methods for accomplishing the same will be more clearly understood from exemplary embodiments described below with reference to the accompanying drawings. However, the present disclosure is not limited to the following exemplary embodiments but may be implemented in various different forms. The exemplary embodiments are provided only to complete disclosure of the present disclosure and to fully provide a person with ordinary skill in the art to which the present disclosure pertains with the category of the disclosure, and the present disclosure will be defined by the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the relation of a position of two parts is described using the terms such as “on”, “above”, “under”, and “next to”, there may be located one or more other parts between the two parts unless the terms are used with the term “immediately” or “directly”.

When the relation of a time sequential order is described using the terms such as “after”, “continuously to”, “next to”, and “before”, the order may not be continuous unless the terms are used with the term “immediately” or “directly”.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

In describing components of the exemplary embodiment of the present disclosure, terminologies such as first, second, A, B, (a), (b), and the like may be used. These terminologies are used to distinguish a component from the other component, but a nature, an order, the number of the components, or the like is not limited by the terminology. When a component is “linked”, “coupled”, or “connected” to another component, the component may be directly linked or connected to the other component. However, unless specifically stated otherwise, it should be understood that a third component may be interposed between the components which may be indirectly linked or connected.

It should be understood that “at least one” includes all combinations of one or more of associated components. For example, “at least one of first, second, and third components” means that not only a first, second, or third component, but also all combinations of two or more of first, second, and third components are included.

In the present disclosure, a “apparatus” may include a display apparatus which includes a display panel and a driver for driving the display panel, in a narrow sense, such as a liquid crystal module (LCM), and an organic light emitting module (OLED module). Further, the “apparatus” may further include a set electronic apparatus or a set apparatus (or a set device) which is a complete product or a final product including an LCM, an OLED module, etc., such as a notebook computer, a television, or a computer monitor, an automotive apparatus or equipment apparatus including another type of vehicle and a mobile electronic apparatus including a smart phone, an electronic pad, etc.

Accordingly, the display apparatus of the present disclosure may include not only a display apparatus itself in a narrow sense such as an LCM, an OLED module, etc., but also an applied product or a set apparatus which is a final consumer device including the LCD, the OLED module, etc.

Further, in some exemplary embodiments, the LCM, the OLED module, etc. which is configured by a display panel, a driver, and the like may be represented as “a display apparatus” in a narrow sense and an electronic device as a complete product including the LCM, and the OLED module may be represented as a “set apparatus”. For example, the display apparatus in the narrow sense includes a liquid crystal (LCD) display panel, an OLED display panel, and a source PCB which is a controller for driving the display panel. In contrast, the set apparatus may be a concept further including a set PCB which is a set controller which is electrically connected to the source PCB to control the entire set apparatus.

As a display panel used in the exemplary embodiment of the present disclosure, any type of display panel such as a liquid crystal display panel, an organic light emitting diode (OLED) display panel,, and an electroluminescent display panel may be used. The display panel of the present exemplary embodiment is not limited thereto. For example, the display panel may be a specific display panel which is vibrated by a vibration device according to an exemplary embodiment of the present disclosure to output a sound. Further, a display panel used for the display apparatus according to the exemplary embodiment of the present disclosure is not limited to a shape or a size of the display panel.

The features of various exemplary embodiments of the present disclosure can be partially or entirely coupled to or combined with each other and can be interlocked and operated in technically various ways, and the exemplary embodiments can be carried out independently of or in association with each other.

Hereinafter, the exemplary embodiment of the present disclosure will be described with reference to the accompanying drawings and exemplary embodiments as follows. Scales of components illustrated in the accompanying drawings are different from the real scales for the purpose of description, so that the scales are not limited to those illustrated in the drawings.

Hereinafter, various exemplary embodiments of the present disclosure will be described in detail with reference to the drawings.

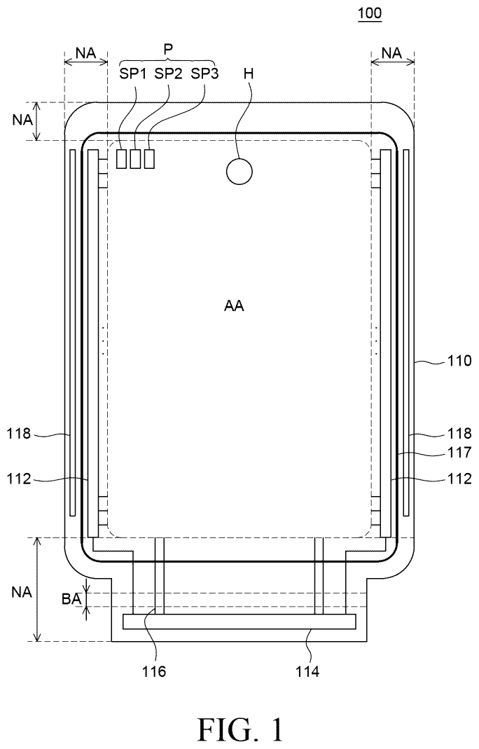

FIG. 1 is a plan view of a display apparatus according to an exemplary embodiment of the present disclosure.

Referring to FIG. 1, a substrate 110 may include an active area (or display area) AA and a non-active area (or non-display area) NA enclosing the active area AA. The non-active area NA of the substrate 110 is adjacent to the active area AA, and may be disposed at an outer portion more than the active area AA.

The active area AA may refer to an area in which pixels P are disposed and images are displayed.

The pixels P disposed in the active area AA may further include a plurality of sub pixels SP1, SP2 and SP3. Each of the plurality of sub pixels SP1, SP2 and SP3 is an individual unit which emits light, and may emit red light, green light, blue light and/or white light. However, exemplary embodiments of the present disclosure are not limited thereto.

The active area AA may include light emitting diode. In each of the plurality of sub pixels SP1, SP2 and SP3, a light emitting diode layer for displaying images and a thin film transistor for driving the light emitting diode layer may be disposed.

Each sub pixel SP may include a plurality of thin film transistors, a capacitor, and a plurality of lines. For example, each sub pixel SP may have a 2T1C structure including two thin film transistors and a capacitor, but is not limited thereto. Each sub pixel SP may be configured in various forms, such as 3T1C, 4T1C, 5T1C, 6T1C, 7T1C, 3T2C, 4T2C, 5T2C, 6T2C, 7T2, and 8T2C, depending on the structures and types of thin film transistors.

FIG. 1 illustrates that the non-active area NA encloses the active area AA having a rectangular shape. However, the shape of the active area AA and the shape and disposition of the non-active area NA adjacent to the active area AA are not limited to the example illustrated in FIG. 1. The active area AA and the non-active area NA may have any shape suitable to the design of an electronic apparatus employing the display apparatus 100. When the display apparatus is employed in a wearable device worn on a user, it may have a circular shape like a watch. Also, the idea of exemplary embodiments of the present disclosure may be employed by free-form display apparatuses applicable to instrument clusters for vehicles, etc. Examples of the shape of the active area AA may include a pentagonal shape, a hexagonal shape, a circular shape, or an oval shape, but the present disclosure is not limited thereto.

The non-active area NA refers to an area in which various wiring lines and driving circuits for driving the plurality of sub pixels SP1, SP2 and SP3 disposed in the active area AA are disposed. For example, various ICs, such as a gate driver and a data driver, and driving circuits may be disposed in the non-active area NA. The non-active area NA may be a bezel area, but is not limited to the terminology.

The display apparatus 100 of the present disclosure may include various additional components for generating various signals or otherwise driving the plurality of sub pixels SP1, SP2 and SP3 in the active area AA. For example, a driving circuit for controlling (or driving) the plurality of sub pixels SP1, SP2 and SP3 may include a gate driver 112, data signal lines, a multiplexer (MUX), an electrostatic discharge (ESD) circuit, a power line, an inverter circuit, a connection line 116, and the like. The power line may be a high potential voltage line and/or a low potential voltage line, but exemplary embodiments of the present disclosure are not limited thereto. The display apparatus 100 may also include an additional component other than a function to drive the plurality of sub pixels SP1, SP2 and SP3. For example, the display apparatus 100 may include additional components which provide a touch sensing function, a user authentication function (for example, fingerprint recognition), a multilevel pressure sensing function, a tactile feedback function, and the like. However, exemplary embodiments of the present disclosure are not limited thereto. The above-described additional components may be located in the non-active area NA or an external circuit connected to a connection interface. However, exemplary embodiments of the present disclosure are not limited thereto.

A pad unit 114 may be disposed at one side of the non-active area NA. The pad unit 114 may be a metal pattern to which an external module, for example, a flexible printed circuit board (FPCB), a chip on film (COF), and the like are bonded. Although it is illustrated that the pad unit 114 is disposed at one side of the substrate 110, the shape and disposition of the pad unit 114 are not limited thereto.

The gate driver 112 may be disposed at one side of the non-active area NA and the other side opposite to the one side. The gate driver 112 may supply gate signals to the thin film transistor. The gate driver 112 may include various gate driving circuits, and the gate driving circuits may be directly formed on the substrate 110. In this case, the gate driver 112 may be a gate-in-panel (GIP), but is not limited to the terminology.

The gate driver 112 may be disposed between the active area AA and a dam 117. A high potential voltage line VDD, a low potential voltage line VSS, a multiplexer (MUX), an electrostatic discharge (ESD) circuit, and the connection line 116 may be disposed between the active area AA and the pad unit 114 of the non-active area NA. However, exemplary embodiments of the present disclosure are not limited thereto.

The high potential voltage line VDD, the low potential voltage line VSS, the multiplexer (MUX), and the connection line 116 may be disposed between the active area AA and a bending area BA, but are not limited thereto. For example, the high potential voltage line VDD, the low potential voltage line VSS, the multiplexer (MUX), and the connection line 116 may be disposed between the active area AA and a non-bending area adjacent thereto.

The connection line 116 may be disposed in a part of the non-active area NA. The connection line 116 may be disposed in the bending area BA of the display apparatus 100 and a non-bending area adjacent to the bending area BA.

The connection line 116 may be a component to transmit a signal (for example, a voltage) from the external module bonded to the pad unit 114 to the active area AA or a circuit unit such as the gate driver 112. For example, various signals and voltages, such as a gate signal, a data signal, a high potential voltage, and a low potential voltage, may be transmitted through the connection line 116.

The connection line 116 may be classified as a power connection line and/or a signal connection line depending on a voltage and/or an image signal to be transmitted.

The power connection line may transmit a voltage supplied from the external module to the active area AA. The power connection line may be connected to the low potential voltage line VSS, the high potential voltage line VDD, and a gate low voltage line and/or a gate high voltage line included in the gate driver 112, but is not limited thereto.

The signal connection line may transmit a signal supplied from the external module to the active area AA. The signal connection line may be connected to a scan line and/or a data line, but is not limited thereto.

The dam 117 may be disposed in a first non-active area NA1 to enclose all or a part of the active area AA. The dam 117 is adjacent to the active area AA, and may be disposed at an outer portion more than the active area AA.

The dam 117 may be disposed along the circumference of the active area AA to control the flow of a layer containing an organic material in an encapsulation unit disposed on the light emitting diode layer. There may be one or more than one dam 117. However, exemplary embodiments of the present disclosure are not limited thereto.

A panel crack detector 118 may be further disposed in a part of the non-active area NA of the substrate 110.

The panel crack detector 118 may be disposed between an end point of the substrate 110 and the dam 117. The panel crack detector 118 may also be disposed under the dam 117 so as to overlap at least a part of the dam 117.

The panel crack detector 118 may be disposed at an outer periphery of the display apparatus 100 to detect defects, such as cracks, which may occur in an outer peripheral portion.

The active area AA may further include a hole H. The hole H may be located between a plurality of sub pixels SP disposed in the active area AA. The hole H may be an area in which an optical component, such as a camera or an optical sensor, is disposed. The optical sensor may include a proximity sensor, an infrared sensor, an ultraviolet sensor, and the like. However, exemplary embodiments of the present disclosure are not limited thereto. The display apparatus 100 may have a space in which the optical component is disposed by means of the hole H which passes through some components of the display apparatus 100.

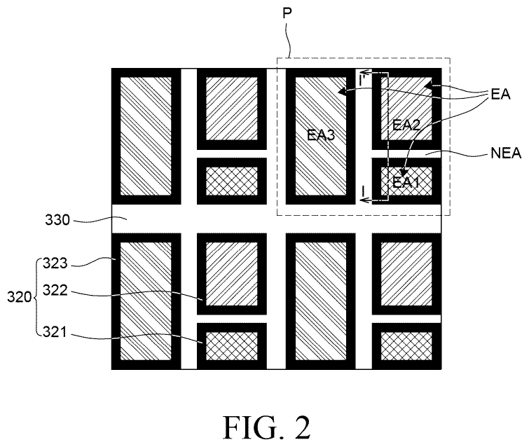

FIG. 2 illustrates the disposition of an emission area and a non-emission area of the display apparatus according to an exemplary embodiment of the present disclosure.

Referring to FIG. 2, an emission area EA refers to an area in a light emitting diode layer of a sub pixel from which light is emitted, and each sub pixel may include an emission area. A plurality of emission areas EA is disposed on the substrate and spaced apart from each other. A non-emission area NEA may be disposed to enclose the emission area.

The emission area EA refers to an area in an emitting layer from which light is emitted to the outside and in which a first bank 320 and a second bank 330 are not disposed. The non-emission area NEA refers to an area in the emitting layer from which light is not emitted to the outside and in which the first bank 320 and the second bank 330 are disposed.

The emission area EA may include a plurality of emission areas which emits light of different colors from each other. For example, the emission area EA may include a first emission area EA1 which emits red light, a second emission area EA2 which emits green light, and a third emission area EA3 which emits blue light. Alternatively, the emission area EA may include a white emission area, etc., but is not limited thereto.

The bank may include the first bank 320 and the second bank 330.

The first bank 320 may be disposed to enclose all or a part of each emission area EA. For example, the first bank 320 may include a first pattern 321, a second pattern 322, and a third pattern 323. The first pattern 321 encloses a first sub pixel SP1 or the first emission area EA1. The second pattern 322 encloses a second sub pixel SP2 or the second emission area EA2. The third pattern 323 encloses a third sub pixel SP3 or the third emission area EA3. The first pattern 321, the second pattern 322, and the third pattern 323 are not connected to each other, and may be spaced apart from each other.

The second bank 330 may be disposed in the non-emission area NEA. For example, the second bank 330 may be continuously disposed in the non-emission area so as to overlap at least a part of the first bank 320 or cover all of the first bank 320.

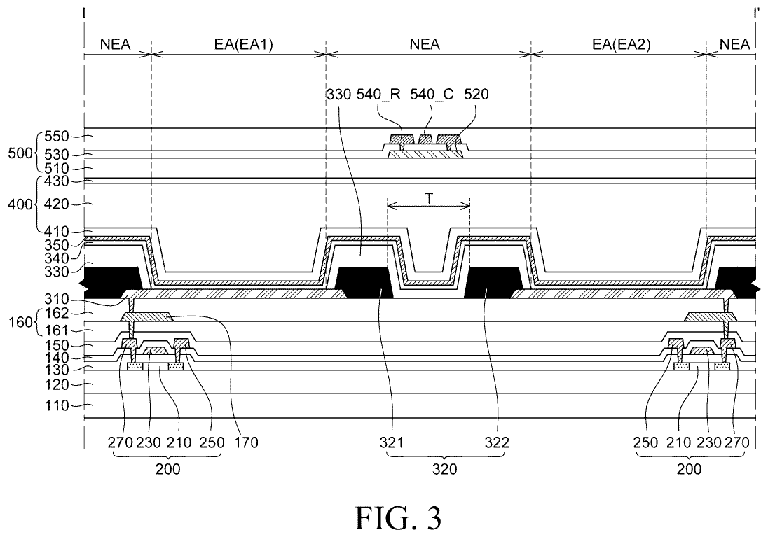

The bank will be described in more detail with reference to FIG. 3.

Each emission area EA is formed to have a specific shape and aligned in a specific form as shown in FIG. 2, but is not limited thereto. The emission area EA of the display apparatus 100 according to the present disclosure may have various shapes or be disposed in various forms. Examples of the shape of the emission area EA may include a rectangular shape, a pentagonal shape, a hexagonal shape, an octagonal shape, a circular shape, or an oval shape, but the present disclosure is not limited thereto. For example, the first emission area EA1 and the third emission area EA3 may have the same shape. The second emission area EA2 may have a different shape from the first emission area EA1. The second emission area EA2 may have a different shape from the third emission area EA3. For example, the second emission area EA2 may have a different shape from the first emission area EA1 and the third emission area EA3.

Each pixel P may be composed of a plurality of sub pixels or emission areas which emit light of the same color. For example, at least two second sub pixels SP2 or second emission areas EA2 may be disposed in a pixel P. At least two second emission areas EA2 which emit green light may be disposed in a pixel P. However, exemplary embodiments of the present disclosure are not limited thereto.

FIG. 3 is a cross-sectional view taken along the line I-I′ of FIG. 2. FIG. 3 illustrates an example of a cross-sectional structure of the area indicated by the line I-I′ of FIG. 2.

Referring to FIG. 3, the substrate 110 may serve to support various components of the display apparatus. The substrate 110 may be made of glass, or a plastic material having flexibility.

For example, the substrate 110 may be made of at least one of polyimide (PI), polymethylmethacrylate (PMMA), polyethylene terephthalate (PET), polyethersulfone, and polycarbonate, but is not limited thereto.

When the substrate 110 is made of polyimide, it may be composed of two polyimide layers. Further, an inorganic film may be further disposed between the two polyimide layers.

The substrate 110 may refer to the substrate itself as well as components and functional layers formed thereon, such as a switching thin film transistor, a driving thin film transistor connected to the switching thin film transistor, an organic light emitting diode connected to the driving thin film transistor, a protection layer, etc. However, the present disclosure is not limited thereto.

A buffer layer 120 may be disposed on the entire surface of the substrate 110.

The buffer layer 120 is disposed on the substrate 110 and may serve to block the flow of a material in the substrate 110 to the thin film transistor or a semiconductor layer during a deposition process.

The buffer layer 120 may be made of an inorganic insulating material such as silicon nitride SiNx or silicon oxide SiOx, or may be made of an organic insulating material, but is not limited thereto.

The buffer layer 120 may be configured by a single layer of silicon nitride SiNx or silicon oxide SiOx or a multi-layer thereof. When the buffer layer 120 is configured by a multi-layer, layers of silicon oxide SiOx and silicon nitride SiNx are alternately laminated. However, exemplary embodiments of the present disclosure are not limited thereto. However, the buffer layer 120 may also be omitted depending on the type and material of the substrate 110, the structure and type of a thin film transistor 200, and the like.

The thin film transistor 200 may be disposed on the buffer layer 120. The thin film transistor 200 may include a semiconductor pattern, a gate electrode, a source electrode, and a drain electrode.

Only one thin film transistor 200 among various thin film transistors is illustrated for convenience in explanation. However, other thin film transistors may also be included in the display apparatus 100. Also, the thin film transistor 200 has been described as having a top gate structure in which a gate electrode constituting the thin film transistor is located on the semiconductor layer for convenience in explanation. However, the thin film transistor 200 is not limited thereto. The thin film transistor 200 may be implemented to have a bottom gate structure in which the gate electrode is located under the semiconductor layer or a double gate structure in which the gate electrode is located on and under the semiconductor layer.

A semiconductor pattern 210 of the thin film transistor 200 may be disposed on the buffer layer 120.

The semiconductor pattern 210 may be made of polycrystalline semiconductor. For example, polycrystalline semiconductor may include low temperature polysilicon (LTPS) having high mobility, but is not limited thereto. When the semiconductor pattern is made of polycrystalline semiconductor, energy power consumption is low and reliability is excellent.

Also, the semiconductor pattern 210 may be made of an oxide semiconductor. For example, the semiconductor pattern 210 may be made of any one of indium-gallium-zinc-oxide (IGZO), indium-zinc-oxide (IZO), indium-gallium-tin-oxide (IGTO), and indium-gallium-oxide (IGO), but is not limited thereto. When the semiconductor pattern 210 is made of the oxide semiconductor, the effect of blocking a leakage current is excellent. Therefore, it is possible to minimize a luminance change of the sub pixels when the thin film transistor is driven at a low speed.

When the semiconductor pattern 210 is made of polycrystalline semiconductor or the oxide semiconductor, a part of the semiconductor pattern 210 may be conductive.

The semiconductor pattern 210 may also be made of amorphous silicon (a-Si), or may be made of various organic semiconductor materials such as pentacene, but is not limited thereto.

A first insulating layer 130 may be disposed on the semiconductor pattern 210 throughout the entire substrate 110.

The first insulating layer 130 is disposed between the semiconductor pattern 210 and a gate electrode 230 to insulate the semiconductor pattern 210 from the gate electrode 230.

The first insulating layer 130 may be made of an inorganic insulating material such as silicon nitride SiNx or silicon oxide SiOx, or may be made of an organic insulating material, but is not limited thereto.

The first insulating layer 130 may include holes for electrically connecting a source electrode 250 and a drain electrode 270 to the semiconductor pattern 210, respectively.

The gate electrode 230 of the thin film transistor 200 may be disposed on the first insulating layer 130. The gate electrode 230 may be disposed to overlap the semiconductor pattern 210.

The gate electrode 230 may be configured by a single layer of any one of molybdenum (Mo), copper (Cu), titanium (Ti), aluminum (Al), chrome (Cr), gold (Au), nickel (Ni), neodymium (Nd), tungsten (W), and a transparent conductive oxide (TCO) or an alloy thereof, or a multi-layer thereof, but is not limited thereto.

A second insulating layer 140 may be disposed on the gate electrode 230 throughout the entire substrate 110.

The second insulating layer 140 is disposed between the gate electrode 230 and the source and drain electrodes 250 and 270 to insulate the gate electrode 230 from the source electrode 250 and the drain electrode 270.

The second insulating layer 140 may include holes for electrically connecting the source electrode 250 and the drain electrode 270 to the semiconductor pattern 210, respectively.

The second insulating layer 140 may be made of an inorganic insulating material such as silicon nitride SiNx or silicon oxide SiOx, or may be made of an organic insulating material, but is not limited thereto.

The source electrode 250 and the drain electrode 270 may be disposed on the second insulating layer 140.

The second insulating layer 140 is disposed between the gate electrode 230 and the source and drain electrodes 250 and 270 to insulate the gate electrode 230 from the source electrode 250 and the drain electrode 270.

The second insulating layer 140 may be made of an inorganic insulating material such as silicon nitride SiNx or silicon oxide SiOx, or may be made of an organic insulating material, but is not limited thereto.

The second insulating layer 140 may include holes for electrically connecting the source electrode 250 and the drain electrode 270 to the semiconductor pattern 210, respectively. The source electrode 250 and the drain electrode 270 may be disposed on the second insulating layer 140.

The source electrode 250 and the drain electrode 270 may be electrically connected to the semiconductor pattern 210 through the holes formed in the first insulating layer 130 and the second insulating layer 140, respectively.

Each of the source electrode 250 and the drain electrode 270 may be configured by a single layer of any one of molybdenum (Mo), copper (Cu), titanium (Ti), aluminum (Al), chrome (Cr), gold (Au), nickel (Ni), neodymium (Nd), tungsten (W), and a transparent conductive oxide (TCO) or an alloy thereof, or a multi-layer thereof, but is not limited thereto. For example, each of the source electrode 250, the drain electrode 270, and a power line VDD may be made of conductive metal materials and may have a three-layer structure of titanium (Ti), aluminum (Al), and titanium (Ti), but is not limited thereto.

A third insulating layer 150 may be disposed on the source electrode 250 and the drain electrode 270 throughout the entire substrate 110. The third insulating layer 150 may be disposed on the thin film transistor 200 to protect the thin film transistor 200. The third insulating layer 150 may be made of an inorganic insulating material such as silicon nitride SiNx or silicon oxide SiOx, or may be made of an organic insulating material, but is not limited thereto.

The third insulating layer 150 may include a hole for electrically connecting the thin film transistor 200 to a connection electrode 170 or a first electrode 310. The third insulating layer 150 may serve as a protection layer, and may also be omitted depending on the structure and type of the thin film transistor 200.

A planarization layer 160 may be disposed on the third insulating layer 150.

The planarization layer 160 may protect the thin film transistor 200 disposed under the planarization layer 160, and may reduce or planarize steps caused by various patterns.

The planarization layer 160 may be disposed as a single layer, but may also be disposed as two or more layers in consideration of the disposition of various electrodes.

This is because as the display apparatus 100 evolves to have a higher resolution, various signal lines are increased. Therefore, it is difficult to dispose all the wiring lines on one layer while securing a minimum interval so that an additional layer needs to be provided. There is a margin in the disposition of the wiring lines by providing such an additional layer, which makes it easier to dispose and design electric wires/electrodes. Further, when a dielectric material is used for the planarization layer 160 configured by a multi-layer, the planarization layer 160 may be used to form a capacitance between metal layers.

When the planarization layer 160 is disposed as two layers, it may include a first planarization layer 161 and a second planarization layer 162.

The first planarization layer 161 and the second planarization layer 162 may be made of at least one material among organic insulating materials, such as benzocyclobutene (BCB), acryl resin, epoxy resin, phenolic resin, polyamide resin, or polyimide resin, but are not limited thereto.

When the planarization layer 160 is composed of two layers, a hole may be formed in the first planarization layer 161 and the connection electrode 170 may be disposed in the hole. The second planarization layer 162 including a hole may be disposed on the first planarization layer 161 and the connection electrode 170. The first electrode 310 may be disposed in the hole of the second planarization layer 162. Therefore, the thin film transistor 200 may be electrically connected to the first electrode 310 through the connection electrode 170.

For example, the connection electrode 170 may be disposed on the first planarization layer 161. An end (or a portion) of the connection electrode 170 may be connected to the thin film transistor 200, and the other end (or another portion) of the connection electrode 170 may be connected to the first electrode 310.

The connection electrode 170 may be configured by a single layer of any one of molybdenum (Mo), copper (Cu), titanium (Ti), aluminum (Al), chrome (Cr), gold (Au), nickel (Ni), neodymium (Nd), tungsten (W), and a transparent conductive oxide (TCO) or an alloy thereof, or a multi-layer thereof, but is not limited thereto.

However, the connection electrode 170 may be omitted based on the structure and type of the display apparatus.

The first electrode 310 may be disposed on the planarization layer 160. The first electrode 310 may serve as an anode.

When the display apparatus 100 is a top emission type, the first electrode 310 may be disposed as a reflective electrode which reflects light and is made of an opaque conductive material. The first electrode 310 may be made of at least one of silver (Ag), aluminum (Al), gold (Au), molybdenum (Mo), tungsten (W), chrome (Cr), or an alloy thereof. For example, the first electrode 310 may be configured to have a three-layer structure of silver (Ag), lead (Pb), and copper (Cu), but is: not limited thereto. Alternatively, the first electrode 310 may further contain a transparent conductive material, such as indium-tin-oxide (ITO), having a high work function.

When the display apparatus 100 is a bottom emission type, the first electrode 310 may be made of a transparent conductive material through which light passes. For example, the first electrode 310 may be made of at least one of indium tin oxide (ITO) and indium zinc oxide (IZO).

The bank may be disposed on the first electrode 310 and the planarization layer 160.

The bank may serve to partition the plurality of sub pixels SP, minimize light glaring, and suppress color mixture at various viewing angles. The bank may separate (or divide) an emission area from which light is emitted and a non-emission area from which light is not emitted, and the bank may be disposed in the non-emission area.

The bank may include the first bank 320 and the second bank 330.

The first bank 320 may be disposed on the planarization layer 160 and the first electrode 310. For example, the first bank 320 may be disposed to cover an end point of the first electrode 310, and may cover upper and side surfaces of the first electrode 310.

The first bank 320 may be disposed to enclose each emission area EA. For example, the first bank 320 may include the first pattern 321, the second pattern 322, and the third pattern 323. The first pattern 321 encloses the first sub pixel SP1 or the first emission area EA1. The second pattern 322 encloses the second sub pixel SP2 or the second emission area EA2. The third pattern 323 encloses the third sub pixel SP3 or the third emission area EA3. The first pattern 321, the second pattern 322, and the third pattern 323 are not connected to each other, and may be spaced apart from each other. An upper surface of the planarization layer 160 may be exposed by the first pattern 321, the second pattern 322, and the third pattern 323. The upper surface of the planarization layer 160 exposed by the first pattern 321, the second pattern 322, and the third pattern 323 may be in contact with the second bank 330.

The first bank 320 may be made of at least one of an inorganic insulating material, an organic insulating material, and a photosensitizer. The inorganic insulating material may be silicon nitride SiNx or silicon oxide SiOx. The organic insulating material may be benzocyclobutene (BCB), acryl resin, epoxy resin, phenolic resin, polyamide resin, or polyimide resin. The photosensitizer may be a black pigment. However, the present disclosure is not limited thereto.

The first bank 320 may contain a light shielding material. Also, the first bank 320 may contain an initiator composed of oligomeric monomers.

Since the first bank 320 contains the black pigment, the first bank 320 further contains a dispersant for suppressing the agglomeration of the black pigment. The dispersant contained in the first bank 320 is made of monomers and oligomers and thus highly likely to be pyrolyzed. Therefore, during a process performed at a high temperature, foreign matters or particles may be generated and may cause deterioration of the display apparatus.

As in the display apparatus 100 according to the exemplary embodiment of the present disclosure, the first bank 320 is disposed in a part of the non-emission area NEA, and, thus, it is possible to reduce the generation of foreign matters or particles and suppress the deterioration of the display apparatus.

The second bank 330 may be disposed on the first bank 320 of the non-emission area NEA and the planarization layer 160. The second bank 330 may be continuously disposed in the non-emission area NEA so as to overlap at least a part of the first bank 320 or cover all of the first bank 320. FIG. 3 illustrates that the second bank 330 covers all of the first bank 320, but the second bank 330 may expose a part of an upper surface of the first bank 320 and may be continuously disposed in the non-emission area NEA. In this case, upper and side surfaces of the first bank 320 may be exposed by the second bank 330 so as to be in contact with a part of a light emitting diode layer 340. That is, the second bank 330 may cover at least a part of an outer surface of the first bank 320. For example, the second bank 330 may cover an entirety of the outer surface of the first bank 320. Alternatively, the second bank 330 may expose an edge portion of the outer surface of the first bank 320, and a projection of the edge portion of the outer surface of the first bank 320 on the substrate 110 may overlap half of a projection of the end point of the first electrode 310 on the substrate 110.

For example, in the cross-sectional view shown in FIG. 3, the length of the end point of the first electrode 310 is 2.5 μm, a length of the projection of the edge portion of the first bank 320 (exposed by the second bank 330) on the substrate 110 is around 1.78 μm. When the second bank 330 covers the entirety of the outer surface of the first bank 320, a side surface of the first bank 320 and the first electrode may have an included angle of 58.4°. When the second bank 330 exposes the edge portion of the outer surface of the first bank 320, a side surface of the first bank 320 and the first electrode may have an included angle of 17.9°.

The second bank 330 may include a trench T formed between the first pattern 321 and the second pattern 322 of the first bank 320 which are spaced apart from each other.

The trench T of the second bank 330 may be formed by removing a part of the first bank 320. The trench T may be obliquely dug from the upper surface, but is not limited thereto. The trench T may be formed into various shapes.

The presence of the trench T formed in the second bank 330 may cause an increase in a placement length of the light emitting diode layer 340 disposed on the second bank 330. For example, the light emitting diode layer 340 formed after the second bank 330 is disposed along the trench T of the second bank 330. Therefore, it is possible to increase a transport distance of electrons in the light emitting diode layer 340 to neighboring sub pixels. Thus, it is possible to suppress the transport of the electrons generated in the light emitting diode layer 340 to the neighboring sub pixels when the display apparatus is driven.

The second bank 330 may include two spacers and a connection section. The two spacers are on the first pattern 321 and the second pattern 322, respectively, and the two spacers protrude toward a direction opposite to the substrate 330. That is, the two spacers protrude toward an encapsulation unit 400 described below. The connection section connects the two spacers to form the trench T.

The second bank 330 may be made of an inorganic insulating material, an organic insulating material, or a transparent material. The inorganic insulating material may be silicon nitride SiNx or silicon oxide SiOx. The organic insulating material may be benzocyclobutene (BCB), acryl resin, epoxy resin, phenolic resin, polyamide resin, or polyimide resin. However, the present disclosure is not limited thereto. The second bank 330 may further contain a light transmitting material.

Since the first bank 320 contains the black pigment, foreign matters or particles are generated. Since the second bank 330 covers the first bank 320, it may block the flow of the foreign matters or particles, which are generated in the first bank 320, within the display apparatus 100.

FIG. 3 illustrates only the first pattern 321 and the second pattern 322, but the same may apply to the third pattern 323.

The light emitting diode layer 340 may be disposed on the first electrode 310 and a first bank 320 and/or second bank 330. The light emitting diode layer 340 may include an emitting layer EML configured to emit light of a specific color for each of the plurality of sub pixels SP1, SP2 and SP3. The emitting layer may serve to emit light. For example, holes generated in the first electrode 310 and electrons generated in a second electrode 350 may be injected into the emitting layer. The holes and electrons injected into the emitting layer may be recombined to generate excitons. Light may be emitted when the generated excitons are shifted from an excited state to a ground state.

For example, the emitting layer may include one of a red emitting layer which emits red light, a green emitting layer which emits green light, a blue emitting layer which emits blue light, and a white emitting layer which emits white light. When the light emitting diode layer 340 includes the white emitting layer, a color filter configured to convert white light emitted from the white emitting layer to light of another color may be disposed on the light emitting diode layer 340. The light emitting diode layer 340 may also include a hole injection layer (HIL), a hole transport layer (HTL), an electron blocking layer (EBL), a hole blocking layer (HBL), an electron transport layer (ETL), and an electron injection layer (EIL) in addition to the emitting layer, but is not limited thereto.

The emitting layer of the light emitting diode layer 340 may be disposed in each of the plurality of sub pixels SP1, SP2 and SP3. Also, the hole injection layer (HIL), the hole transport layer (HTL), the electron blocking layer (EBL), the hole blocking layer (HBL), the electron transport layer (ETL), and the electron injection layer (EIL) of the light emitting diode layer 340 may be disposed in the entire active area AA.

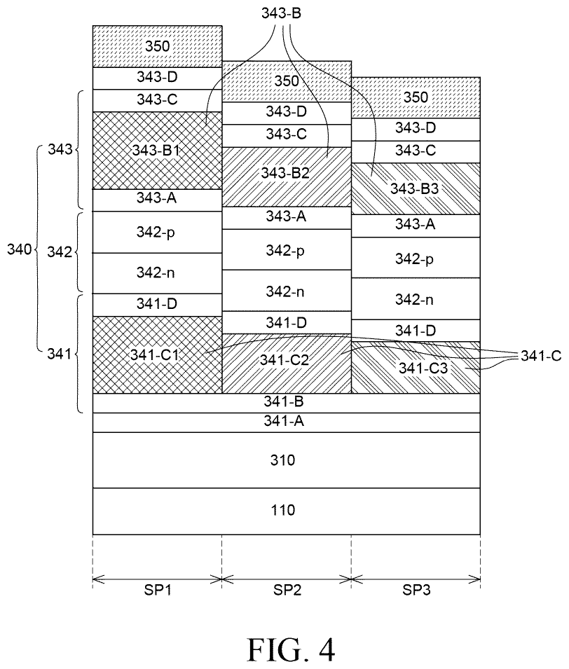

The light emitting diode layer 340 of the display apparatus 100 according to the exemplary embodiment of the present disclosure may be an emitting unit. The emitting unit may be disposed as at least one light emitting diode layer. For example, the emitting unit may have a stack structure formed by laminating a plurality of light emitting diode layers between the first electrode 310 and the second electrode 350. In this case, a charge generation layer may be further disposed between the plurality of light emitting diode layers. A plurality of emitting units may be disposed in each sub pixel SP. The emitting unit will be described in detail with reference to FIG. 4.

The second electrode 350 may be disposed on the light emitting diode layer 340. The second electrode 350 may serve as a cathode. The second electrode 350 may supply electrons to the light emitting diode layer 340 and may be made of a conductive material having a low work function.

When the display apparatus 100 is a top emission type, the second electrode 350 may be made of a transparent conductive material through which light passes. For example, the second electrode 350 may be made of at least one of indium tin oxide (ITO) and indium zinc oxide (IZO), but is not limited thereto.

Also, the second electrode 350 may be made of a translucent conductive material through which light passes. For example, the second electrode 350 may be made of at least one of alloys, such as LiF/Al, CsF/Al, Mg:Ag, Ca/Ag, Ca:Ag, LiF/Mg:Ag, LiF/Ca/Ag, and LiF/Ca:Ag, but is not limited thereto.

When the display apparatus 100 is a bottom emission type, the second electrode 350 may be disposed as a reflective electrode which reflects light and is made of an opaque conductive material. For example, the second electrode 350 may be made of at least one of silver (Ag), aluminum (Al), gold (Au), molybdenum (Mo), tungsten (W), chrome (Cr), or an alloy thereof.

An encapsulation unit 400 may be disposed on the second electrode 350. The encapsulation unit 400 may protect the light emitting diode layer 340 from external moisture, oxygen or foreign matters. For example, the encapsulation unit 400 may suppress the permeation of oxygen and moisture from the outside to suppress the oxidation of a light emitting material and an electrode material.

The encapsulation unit 400 may be made of a transparent material so that light emitted from the light emitting diode layer 340 may be transmitted to the encapsulation unit 400.

The encapsulation unit 400 may include a first encapsulation layer 410, a second encapsulation layer 420, and a third encapsulation layer 430 to block the permeation of moisture or oxygen. Herein, the encapsulation unit 400 may have a structure in which the first encapsulation layer 410, the second encapsulation layer 420, and the third encapsulation layer 430 are alternately laminated.

The first encapsulation layer 410 and the third encapsulation layer 430 may be made of at least one inorganic material of silicon nitride SiNx, silicon oxide SiOx, or aluminum oxide AlyOz, but is not limited thereto. The first encapsulation layer 410 and the third encapsulation layer 430 may be formed using a vacuum deposition method such as a chemical vapor deposition (CVD), an atomic layer deposition (ALD), or the like, but is not limited thereto.

The first encapsulation layer 410 and the third encapsulation layer 430 may be composed of at least two layers. For example, the first encapsulation layer 410 may have a three-layer structure of silicon oxide SiOx, silicon nitride SiNx, and silicon oxide SiOx, but is not limited thereto. Alternatively, the first encapsulation layer 410 may have a four-layer structure of silicon oxide SiOx, silicon nitride SiNx, silicon oxide SiOx, and silicon oxide SiOx, but is not limited thereto.

The second encapsulation layer 420 may cover foreign matters or particles which may be generated during the manufacturing process. Also, the second encapsulation layer 420 may planarize the surface of the first encapsulation layer 410. For example, the second encapsulation layer 420 may serve as a particle cover layer, but is not limited to the terminology.

The second encapsulation layer 420 may be made of an organic material, for example, a polymer such as silicon oxy carbon SiOCz, epoxy, polyimide, polyethylene, or acrylate, but is not limited thereto.

The second encapsulation layer 420 may be made of a thermosetting material or a photocurable material which is hardened by heat or light.

The first encapsulation layer 410 may extend to the non-active area NA. For example, the first encapsulation layer 410 may be disposed to cover the dam 117. The third encapsulation layer 430 may extend to the non-active area NA. For example, the third encapsulation layer 430 may be disposed on the first encapsulation layer 410 so as to cover the dam 117.

A touch unit 500 may be disposed on the encapsulation unit 400.

The touch unit 500 may include a first touch electrode 540_R, a first touch connection electrode 520, a second touch electrode, and a second touch connection electrode 540_C.

Parts of the first touch electrode 540_R, the first touch connection electrode 520, the second touch electrode, and the second touch connection electrode 540_C may be disposed to overlap the bank 420.

The first touch electrode 540_R, the second touch electrode, the first touch connection electrode 520, and the second touch connection electrode 540_C may be formed to have a mesh pattern in which metal lines each having a small line width intersect each other. The mesh pattern may have a rhombic shape. The mesh pattern may also have a rectangular shape, a pentagonal shape, a hexagonal shape, a circular shape, an oval shape, or the like, but is not limited thereto.

The first touch electrode 540_R, the second touch electrode, the first touch connection electrode 520, and the second touch connection electrode 540_C may be made of an opaque conductive material having a low resistance. For example, each of the electrodes may be configured by a single layer of molybdenum (Mo), copper (Cu), titanium (Ti), aluminum (Al), chrome (Cr), gold (Au), nickel (Ni), neodymium (Nd), tungsten (W), and a transparent conductive oxide (TCO) or an alloy thereof, or a multi-layer thereof, but is not limited thereto.

For example, each of the first touch electrode 540_R, the second touch electrode, the first touch connection electrode 520, and the second touch connection electrode 540_C may be made of conductive metal materials and may have a three-layer structure of titanium (Ti), aluminum (Al), and titanium (Ti), but is not limited thereto.

The first touch electrode 540_R, the second touch electrode, the first touch connection electrode 520, and the second touch connection electrode 540_C may be made of the same material as the source electrode 250 and the drain electrode 270.

A touch buffer layer 510 may be disposed on the encapsulation unit 400. The touch buffer layer 510 may block the permeation of chemicals (for example, developer, etchant, etc.) used for the manufacturing process of the touch unit 500 or moisture from the outside into the light emitting diode layer 340 containing an organic material. Also, the touch buffer layer 510 may suppress a short-circuit of a plurality of touch sensor metals on the touch buffer layer 510 caused by external impacts. Further, the touch buffer layer 510 may block an interference signal which may be generated when the touch unit is driven.

The touch buffer layer 510 may be made of at least one of an inorganic insulating material and an organic insulating material. The inorganic insulating material may be silicon nitride SiNx or silicon oxide SiOx. The organic insulating material may be benzocyclobutene (BCB), acryl resin, epoxy resin, phenolic resin, polyamide resin, or polyimide resin. The touch buffer layer 510 may be configured by a multi-layer touch buffer layer 510, but is not limited thereto.

The first touch connection electrode 520 may be disposed on the touch buffer layer 510.

For example, the first touch connection electrode 520 may be disposed between the first touch electrodes 540_R adjacent to each other in a first direction (or X-axis direction). The first touch connection electrode 520 may electrically connect a plurality of first touch electrodes 540_R spaced apart from and disposed adjacent to each other in the first direction (or X-axis direction), but is not limited thereto.

The first touch connection electrode 520 may be disposed to overlap the second touch connection electrode 540_C which connects the second touch electrodes adjacent to each other in a second direction (or Y-axis direction). The first touch connection electrode 520 and the second touch connection electrode 540_C are disposed on different layers and thus may be electrically insulated from each other.

A touch insulating layer 530 may be disposed on the touch buffer layer 510 and the first touch connection electrode 520.

The touch insulating layer 530 may include a hole for electrically connecting the first touch electrode 540_R to the first touch connection electrode 520.

The touch insulating layer 530 may serve to electrically insulate the second touch electrode from the second touch connection electrode 540_C.

The touch insulating layer 530 may be configured by a single layer of silicon nitride SiNx or silicon oxide SiOx or a multi-layer thereof, but is not limited thereto.

The first touch electrode 540_R, the second touch electrode, and the second touch connection electrode 540_C may be disposed on the touch insulating layer 530.

The first touch electrode 540_R and the second touch electrode may be disposed to be spaced apart from each other by a predetermined distance. At least one first touch electrode 540_R adjacent to each other in the first direction (or X-axis direction) may be spaced apart from each other. The least one first touch electrode 540_R adjacent to each other in the first direction (or X-axis direction) may be connected to the first touch connection electrode 520 between a plurality of first touch electrodes 540_R. For example, the plurality of first touch electrodes 540_R adjacent to each other may be connected to the first touch connection electrode 520 through the hole formed in the touch insulating layer 530.

The second touch electrodes adjacent to each other in a second direction (or Y-axis direction) may be connected by the second touch connection electrode 540_C. The second touch electrode and the second touch connection electrode 540_C may be disposed on the same layer. For example, the second touch connection electrode 540_C may be disposed between a plurality of second touch electrodes on the same layer as the second touch electrodes. The second touch connection electrode 540_C may extend from the second touch electrodes.

The first touch electrode 540_R, the second touch electrode, and the second touch connection electrode 540_C may be formed by the same process.

A touch planarization layer 550 may be disposed on the first touch electrode 540_R, the second touch electrode, and the second touch connection electrode 540_C.

A touch driving circuit may receive a touch sensing signal from the first touch electrode 540_R. Also, the touch driving circuit may transmit a touch driving signal from the second touch electrode. The touch driving circuit may sense a user's touch by using a mutual capacitance between the plurality of first touch electrodes 540_R and the second touch electrode. For example, when the display apparatus 100 is touched, a capacitance between the first touch electrodes 540_R and the second touch electrode may change. The touch driving circuit may sense such a change in the capacitance and detect the coordinates of the touch.

FIG. 4 is a cross-sectional view of an emitting unit of the display apparatus according to an exemplary embodiment of the present disclosure.

FIG. 4 illustrates only two light emitting diode layers for convenience in explanation. However, the emitting unit may include two or more light emitting diode layers and may further include one or more charge generation layers between the two or more light emitting diode layers.

The light emitting diode layer 340 of the display apparatus 100 according to the present disclosure may be an emitting unit. The emitting unit may include at least one light emitting diode layer 340. For example, the emitting unit may have a stack structure formed by laminating a plurality of light emitting diode layers between the first electrode 310 and the second electrode 350. In this case, a charge generation layer may be further disposed between the plurality of light emitting diode layers. A plurality of emitting units may be disposed in each sub pixel SP.

When the light emitting diode layer 340 is configured as the emitting unit, the emitting unit may include a first light emitting diode layer 341, a second light emitting diode layer 343, and a charge generation layer 342 between the first light emitting diode layer 341 and the second light emitting diode layer 343.

The presence of the trench T formed in the second bank 330 may cause an increase in a placement length of the emitting unit disposed on the second bank 330. For example, the emitting unit is disposed along a curve of the trench T formed in the second bank 330. Therefore, it is possible to increase a transport distance of electrons of a layer constituting the emitting unit to neighboring sub pixels and thus to suppress the transport of the electrons generated in the emitting unit to the neighboring sub pixels when the display apparatus is driven.

The first electrode 310, the first light emitting diode layer 341, the charge generation layer 342, the second light emitting diode layer 343, and the second electrode 350 may be sequentially disposed on the substrate 110 including the first sub pixel SP1, the second sub pixel SP2, and the third sub pixel SP3.

The first light emitting diode layer 341 may include a hole injection layer 341-A, a first hole transport layer 341-B, a first emitting layer 341-C, and a first electron transport layer 341-D.

The second light emitting diode layer 343 may include a second hole transport layer 343-A, a second emitting layer 343-B, a second electron transport layer 343-C, and an electron injection layer 343-D.

The charge generation layer 342 may further include an n-type charge generation layer (n-CGL) 342-n and a p-type charge generation layer (p-CGL) 342-p. The n-type charge generation layer 342-n assists electron injection to the first light emitting diode layer 341, and the p-type charge generation layer 342-p assists hole injection to the second light emitting diode layer 343.

The first emitting layer 341-c and the second emitting layer 343-B may be disposed in patterns spaced apart from each other so as to correspond to respective sub pixels. For example, the first emitting layer 341-C and the second emitting layer 343-B may be disposed on at least a part of an end point of the bank.

The hole injection layer 341-A may serve to facilitate hole injection. The hole injection layer 341-A may be made of any one or more selected from the group consisting of HATCN (1,4,5,8,9,11-hexaazatriphenylene-hexanitrile), CuPc (copper phthalocyanine), PEDOT (poly(3,4)-ethylenedioxythiophene), PANI (polyaniline), and NPD (N,N-dinaphthyl-N,N′-diphenylbenzidine), but is not limited thereto.

The first hole transport layer 341-B and the second hole transport layer 343-A may serve to facilitate hole transport. The first hole transport layer 341-B and the second hole transport layer 343-A may be made of any one or more selected from the group consisting of NPD (N,N-dinaphthyl-N,N′-diphenylbenzidine), TPD (N,N′-bis-(3-mePHylphenyl)-N,N′-bis-(phenyl)-benzidine), s-TAD, and MTDATA (4,4′,4″-Tris(N-3-mePHylphenyl-N-phenyl-amino)-triphenylamine), but are not limited thereto.

The first electron transport layer 341-D and the second electron transport layer 343-C may serve to facilitate electron transport. The first electron transport layer 341-D and the second electron transport layer 343-C may be made of any one or more selected from the group consisting of Alq3(tris(8-hydroxyquinolino)aluminum), PBD (2-(4-biphenylyl)-5-(4-tert-butylpheny)-1,3,4oxadiazole), TAZ, spiro-PBD, BAlq, and SAlq, but are not limited thereto.

The electron injection layer 343-D may serve to facilitate electron injection. The electron injection layer 343-D may be made of Alq3 (tris(8-hydroxyquinolino)aluminum), PBD (2-(4-biphenylyl)-5-(4-tert-butylpheny)-1,3,4oxadiazole), TAZ, spiro-PBD, BAlq, or SAlq, but is not limited thereto.

The first emitting layer 341-C and the second emitting layer 343-B may be disposed in the emission area EA and disposed on the first bank 320 or the second bank 330. Also, the first emitting layer 341-C and the second emitting layer 343-B may be spaced apart from each other between neighboring sub pixels. For example, the first emitting layer 341-C and the second emitting layer 343-B may be deposited on each sub pixel by using a fine metal mask (FMM).

The first emitting layer 341-C may overlap the second emitting layer 343-B. The first emitting layer 341-C and the second emitting layer 343-B may contain light emitting materials emitting light of red, green, and blue, respectively. The light emitting materials may be prepared using a phosphorescent or fluorescent material.

For example, a first red emitting layer 341-C1 and a second red emitting layer 343-B1 disposed in the first sub pixel SP1 may be made of a phosphorescent material including a host material and a dopant material. The host material may include CBP (carbazole biphenyl) or mCP(1,3-bis(carbazol-9-yl)). The dopant material may include any one or more selected from the group consisting of PIQIr(acac) (bis(1-phenylisoquinoline) acetylacetonate iridium), PQIr(acac) (bis(1-phenylquinoline) acetylacetonate iridium), PQIr (tris(1-phenylquinoline) iridium), and PtOEP (octaethylporphyrin platinum). Alternatively, the first red emitting layer 341-C1 and the second red emitting layer 343-B1 may be made of a fluorescent material including PBD:Eu(DBM)3(Phen) or perylene, but are not limited thereto.

A first green emitting layer 341-C2 and a second green emitting layer 343-B2 disposed in the second sub pixel SP2 may be made of a phosphorescent material including a host material and a dopant material. The host material may include CBP or mCP. The dopant material may be an Ir complex including Ir(ppy)3 (fac tris(2-phenylpyridine)iridium). Alternatively, the first green emitting layer 341-C2 and the second green emitting layer 343-B2 may be made of a fluorescent material including Alq3 (tris(8-hydroxyquinolino)aluminum), but are not limited thereto.

A first blue emitting layer 341-C3 and a second blue emitting layer 343-B3 disposed in the third sub pixel SP3 may be made of a phosphorescent material including a host material and a dopant material. The host material may include CBP or mCP, and the dopant material may include (4,6-F2ppy)2Irpic. Alternatively, the first blue emitting layer 341-C3 and the second blue emitting layer 343-B3 may be made of a fluorescent material including any one selected from the group consisting of spiro-DPVBi, spiro-6P, distylbenzene (DSB), distyrylarylrene (DSA), a PFO-based polymer, and a PPV-based polymer, but are not limited thereto.

The first emitting layer 341-C and the second emitting layer 343-B may further include auxiliary emitting layers, respectively. For example, the auxiliary emitting layers may be disposed under or on each of the first emitting layer 341-C and the second emitting layer 343-B. The auxiliary emitting layers may emit light of the same color as or different colors from light emitted from the first emitting layer 341-C and the second emitting layer 343-B, respectively.

The n-type charge generation layer 342-n may be made of an alkali metal, an alkali metal compound, an organic material which injects electrons, or a compound thereof. For example, the n-type charge generation layer 342-n may be configured by a mixed layer of n-type materials, such as an anthracene derivative doped with cesium (Cs) and lithium (Li), but is not limited thereto.

The p-type charge generation layer 342-p may be made of an organic material used as a hole injection layer. For example, the p-type charge generation layer 342-p may be configured by a single layer of p-type materials, such as HATCN and F4-TCNQ, but is not limited thereto.

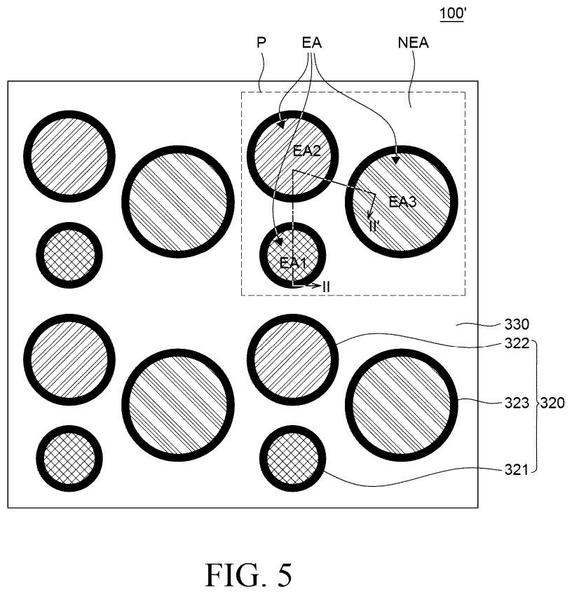

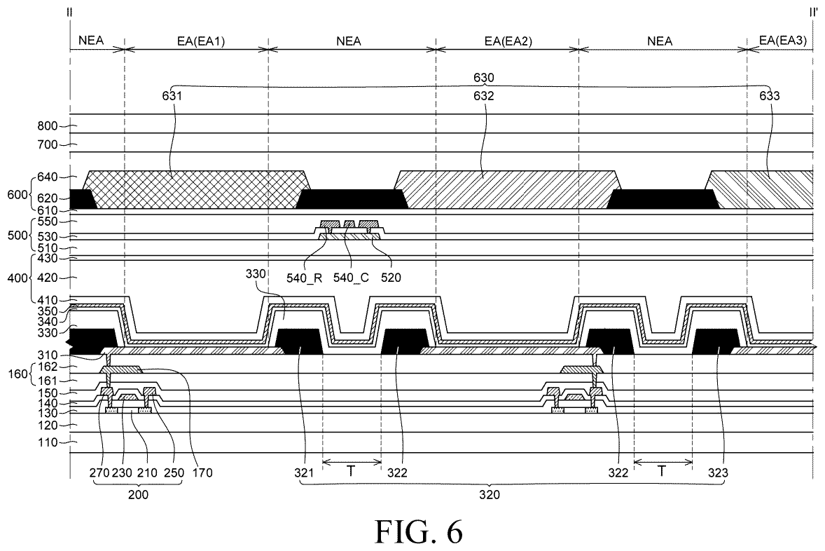

Some components of the emitting unit may be disposed in the entire active area AA. For example, the charge generation layer 342, the hole injection layer 341-A, the hole transport layers 341-B and 343-A, the electron transport layer 341-D and 343-C, and the electron injection layer 343-D are continuously disposed in the plurality of sub pixels SP1, SP2 and SP3. Therefore, a separation distance between the sub pixels decreases, and, thus, image information may be distorted by a lateral leakage current between neighboring pixels. However, the emitting unit is disposed along the curve formed on the bank, and, thus, a transport distance of electrons to the neighboring sub pixels increases. Therefore, it is possible to suppress the transport of electrons generated in the light emitting diode layer to the neighboring pixels when the display apparatus is driven. FIG. 5 illustrates the disposition of an emission area and a non-emission area of the display apparatus according to another exemplary embodiment of the present disclosure. FIG. 6 is a cross-sectional view taken along the line II-II′ of FIG. 5. A display apparatus 100′ shown in FIG. 5 and FIG. 6 is substantially identical to the display apparatus 100 shown in FIG. 1 through FIG. 4 except a color filter and the disposition of sub pixels. Therefore, repeated description of the same components is omitted for brevity.

Referring to FIG. 5, the emission area EA may have a circular shape, an oval shape, or a polygonal shape in a plan view. The emission areas EA of the respective sub pixels may have different sizes from each other.

A plurality of emission areas which emits light of different colors from each other may be located in the emission area EA. For example, the emission area EA may include the first emission area EA1 which emits red light, the second emission area EA2 which emits green light, and the third emission area EA3 which emits blue light. Alternatively, the emission area EA may include a white emission area, but is not limited thereto.

The bank may include the first bank 320 and the second bank 330.

The first bank 320 may be disposed to enclose all or a part of each emission area EA. For example, the first bank 320 may include the first pattern 321, the second pattern 322, and the third pattern 323. The first pattern 321 encloses the first sub pixel SP1 or the first emission area EA1. The second pattern 322 encloses the second sub pixel SP2 or the second emission area EA2. The third pattern 323 encloses the third sub pixel SP3 or the third emission area EA3. The first pattern 321, the second pattern 322, and the third pattern 323 are not connected to each other, and may be spaced apart from each other.

The second bank 330 may be disposed in the non-emission area NEA. For example, the second bank 330 may be continuously disposed in the non-emission area so as to overlap at least a part of the first bank 320 or cover all of the first bank 320.

Referring to FIG. 6, a color filter unit 600 may be further disposed on the touch unit 500. The color filter unit 600 may include a plurality of color filters and a black matrix.

A fourth insulating layer 610 may be disposed on the touch unit 500. The fourth insulating layer 610 may be made of an inorganic insulating material such as silicon nitride SiNx or silicon oxide SiOx, or may be made of an organic insulating material, but is not limited thereto.

The fourth insulating layer 610 may also be omitted depending on the structure and type of the thin film transistor 200.

A black matrix 620 may be disposed on the fourth insulating layer 610 in the non-emission area NEA.

The black matrix 620 may be disposed between the plurality of color filters to suppress color mixture.

The black matrix 620 may be made of at least one of an inorganic insulating material, an organic insulating material, and a photosensitizer. The inorganic insulating material may be silicon nitride SiNx or silicon oxide SiOx. The organic insulating material may be benzocyclobutene (BCB), acryl resin, epoxy resin, phenolic resin, polyamide resin, or polyimide resin. The photosensitizer may be a black pigment. However, the present disclosure is not limited thereto.

The black matrix 620 may at least overlap the first bank 320. The black matrix 620 may overlap the trench T of the second bank 330. Alternatively, a part of the first bank 320 may overlap the black matrix 620. One part of the first bank 320 may overlap the black matrix 620, and the other part of the first bank 320 may be more adjacent to the emission area than the one part of the first bank 320 and may overlap the color filter. The other part of the first bank 320 may not overlap the black matrix 620.

In the display apparatus 100′ according to another exemplary embodiment of the present disclosure, a gap in the first bank 320 overlaps the black matrix 620. Therefore, even when light incident from the outside of the display apparatus 100′ is reflected, it may have almost no effect.

A color filter 630 may be disposed on the fourth insulating layer in the emission area EA.

The color filter 630 may be composed of a plurality of color filters. For example, the color filter 630 may include a first color filter 631, a second color filter 632, and a third color filter 633.

The first color filter 631 is disposed corresponding to the first sub pixel SP1, and may contain a red color filter material. The second color filter 632 is disposed corresponding to the second sub pixel SP2, and may contain a green color filter material. The third color filter 633 is disposed corresponding to the third sub pixel SP3, and may contain a red color filter material.

End points of the first color filter 631, the second color filter 632, and the third color filter 633 may be disposed on the black matrix 620 and may cover end points of the black matrix 620.

FIG. 6 illustrates that the first color filter 631, the second color filter 632, and the third color filter 633 are spaced apart from each other. However, the first color filter 631, the second color filter 632, and the third color filter 633 may be in contact with each other, or at least parts of them may overlap each other.

An overcoating layer 640 may be disposed on the color filter 630.

The overcoating layer 640 may protect the color filter 630 and the black matrix 620 disposed under the overcoating layer 640, and may reduce or planarize steps.

An adhesive layer 700 may be disposed on the overcoating layer 640.

The color filter unit 600 may be bonded to a front member 800 by using the adhesive layer 700.

The adhesive layer 700 may be made of a material having adhesive properties. The adhesive layer 700 may be made of, for example, optically clear adhesive (OCA), pressure sensitive adhesive (PSA), or the like, but is not limited thereto.

The front member 800 may be disposed on the adhesive layer 700.

The front member 800 may protect a display driving part DISP, the touch unit 500, and the like disposed under the front member 800 from external impacts, moisture, heat, and the like. The front member 800 may be made of a material having impact resistance and light transmittance. For example, the front member 800 may be a substrate made of glass. Also, the front member 800 may be a film made of a plastic material such as polymethylmethacrylate (PMMA), polyimide (PI), and polyethylene terephthalate (PET), but is not limited thereto. Further, the front member 800 may also be referred to by various names, such as a cover window, a window cover, or a cover glass, but is not limited thereto.

The front member 800 may be bonded to the substrate 110 by a bonding process after the manufacturing process of the components disposed on the substrate 110 is completed.

If the color filter unit 600 is further provided on the touch unit 500 as in another exemplary embodiment, a polarizing plate used for reflectance reduction may be removed. For example, when light is incident into the display apparatus 100 from the outside, the light may be reflected by wiring lines or patterns made of metals in the display apparatus 100 and then transmitted to the outside. In this case, when power is off, the wiring lines or patterns made of metals in the display apparatus 100 can be recognized by the user of the display apparatus 100. However, since the color filter unit 600 is further provided, the black matrix of the color filter unit 600 can block light even when the light is reflected by the wiring lines or patterns made of metals in the display apparatus 100. Therefore, the polarizing plate may not be provided.

The foregoing exemplary embodiments are briefly described below.

A display apparatus according to an exemplary embodiment of the present disclosure includes: a substrate including a first sub pixel and a second sub pixel; a first electrode disposed in each of the first sub pixel and the second sub pixel; and a bank disposed to cover an end point of the first electrode and separating an emission area and a non-emission area which encloses the emission area. Herein, the bank may include a first bank disposed on the first electrode, and a second bank disposed on the first bank and including a trench.

In the display apparatus according to the exemplary embodiment of the present disclosure, the first bank may contain a material including a black pigment, and the second bank may contain a transparent material.

In the display apparatus according to the exemplary embodiment of the present disclosure, the first bank may contain an initiator of oligomeric monomers.

In the display apparatus according to the exemplary embodiment of the present disclosure, the first bank may include: a first pattern enclosing the first electrode of the first sub pixel; and a second pattern enclosing the first electrode of the second sub pixel and spaced apart from the first pattern.

In the display apparatus according to the exemplary embodiment of the present disclosure, the second bank may enclose all of upper and side surfaces of the first bank and may be continuously disposed in the non-emission area.

In the display apparatus according to the exemplary embodiment of the present disclosure, the second bank may expose a part of an upper surface of the first bank and may be continuously disposed in the non-emission area.

The display apparatus according to the exemplary embodiment of the present disclosure may further include a planarization layer disposed between the substrate and the first electrode. An upper surface of the planarization layer may be exposed by the first pattern and the second pattern.

In the display apparatus according to the exemplary embodiment of the present disclosure, the upper surface of the planarization layer exposed by the first pattern and the second pattern may be in contact with the second bank.

The display apparatus according to the exemplary embodiment of the present disclosure may further include an emitting unit including a plurality of emitting layers disposed on the first electrode and the second bank and a charge generation layer disposed between the plurality of emitting layers.

In the display apparatus according to the exemplary embodiment of the present disclosure, the emitting unit may be disposed on the second bank and comprise a curve.

The display apparatus according to the exemplary embodiment of the present disclosure may further include: an encapsulation unit disposed on the emitting unit; a touch unit disposed on the encapsulation unit; and a color filter unit disposed on the touch unit.

In the display apparatus according to the exemplary embodiment of the present disclosure, the color filter unit may include: an insulating layer disposed on the touch unit; a black matrix disposed on the insulating layer in the non-emission area; and a color filter disposed on the black matrix so as to correspond to the first sub pixel and the second sub pixel.

In the display apparatus according to the exemplary embodiment of the present disclosure, the first bank may include: a first portion overlapping the black matrix and the color filter; and a second portion overlapping the color filter.

A display apparatus according to an exemplary embodiment of the present disclosure includes: a substrate including an active area including a plurality of sub pixels and a non-active area; a plurality of light emitting diodes disposed in the plurality of sub pixels, respectively, and including a first electrode, an emitting unit, and a second electrode; a plurality of first banks disposed to cover an end point of the first electrode of the plurality of light emitting diodes and spaced apart from each other; and a second bank disposed on the end point of the first electrode of the plurality of light emitting diodes and the plurality of first banks and including a trench.

In the display apparatus according to the exemplary embodiment of the present disclosure, the first bank may contain a light shielding material, and the second bank may contain a light transmitting material.

In the display apparatus according to the exemplary embodiment of the present disclosure, the first bank may include: a first pattern enclosing a first electrode of a first sub pixel, and a second pattern enclosing a first electrode of a second sub pixel and spaced apart from the first pattern.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a substrate including a first sub pixel and a second sub pixel;
a first electrode disposed in each of the first sub pixel and the second sub pixel; and
a bank disposed to cover an end point of the first electrode and separating an emission area and a non-emission area which encloses the emission area,
wherein the bank includes a first bank disposed on the first electrode, and a second bank disposed on the first bank and including a trench.

2. The display apparatus according to claim 1, wherein the first bank contains a material including a black pigment, and the second bank contains a transparent material.

3. The display apparatus according to claim 2, wherein the first bank contains an initiator of oligomeric monomers.

4. The display apparatus according to claim 1, wherein the first bank includes:
a first pattern enclosing the first electrode of the first sub pixel; and
a second pattern enclosing the first electrode of the second sub pixel and spaced apart from the first pattern.

5. The display apparatus according to claim 4, wherein the second bank encloses all of upper and side surfaces of the first bank and is continuously disposed in the non-emission area.

6. The display apparatus according to claim 4, wherein the second bank exposes a part of an upper surface of the first bank and is continuously disposed in the non-emission area.

7. The display apparatus according to claim 5, further comprising:
a planarization layer disposed between the substrate and the first electrode,
wherein an upper surface of the planarization layer is exposed by the first pattern and the second pattern.

8. The display apparatus according to claim 7, wherein the upper surface of the planarization layer exposed by the first pattern and the second pattern is in contact with the second bank.

9. The display apparatus according to claim 1, further comprising:
an emitting unit including a plurality of emitting layers disposed on the first electrode and the second bank and a charge generation layer disposed between the plurality of emitting layers.

10. The display apparatus according to claim 9, wherein the emitting unit is disposed on the second bank and comprises a curve.

11. The display apparatus according to claim 9, further comprising:
an encapsulation unit disposed on the emitting unit;
a touch unit disposed on the encapsulation unit; and
a color filter unit disposed on the touch unit.

12. The display apparatus according to claim 11, wherein the color filter unit includes:
an insulating layer disposed on the touch unit;
a black matrix disposed on the insulating layer in the non-emission area; and
a color filter disposed on the black matrix so as to correspond to the first sub pixel and the second sub pixel.

13. The display apparatus according to claim 12, wherein the first bank includes:
a first portion overlapping the black matrix and the color filter; and
a second portion overlapping the color filter.

14. A display apparatus, comprising:
a substrate including a first sub pixel and a second sub pixel;
a first electrode disposed in each of the first sub pixel and the second sub pixel; and
a bank disposed to cover an end point of the first electrode and separating an emission area and a non-emission area which encloses the emission area,
wherein the bank includes:
a first bank disposed on the first electrode and containing a material including a black pigment; and
a second bank disposed on the first bank and covering at least a part of an outer surface of the first bank, and the second bank containing a transparent material.

15. The display apparatus according to claim 14, wherein the second bank covers an entirety of the outer surface of the first bank.

16. The display apparatus according to claim 14, wherein the second bank exposes an edge portion of the outer surface of the first bank, and a projection of the edge portion of the outer surface on the substrate overlaps half of a projection of the end point of the first electrode on the substrate.

17. The display apparatus according to claim 14, wherein the second bank includes a trench.

18. The display apparatus according to claim 17, further comprising:
a light emitting diode layer disposed on the second bank and the first electrode; and
a second electrode disposed on the light emitting diode layer.

19. The display apparatus according to claim 17, wherein the second bank is continuously disposed in the non-emission area.

20. The display apparatus according to claim 17, wherein the second bank includes:
two spacers protruding toward a direction opposite to the substrate; and
a connecting section connecting the two spacers,
wherein the connecting section forms the trench.

21. The display apparatus according to claim 14, further comprising:
an emitting unit including a plurality of emitting layers disposed on the first electrode and the second bank;
an encapsulation unit disposed on the emitting unit;
a touch unit disposed on the encapsulation unit; and
a color filter unit disposed on the touch unit.

22. The display apparatus according to claim 21, wherein the color filter unit includes:
an insulating layer disposed on the touch unit;
a black matrix disposed on the insulating layer in the non-emission area; and
a color filter disposed on the black matrix so as to correspond to the first sub pixel and the second sub pixel.

23. The display apparatus according to claim 14, wherein the first bank includes:
a first pattern enclosing the first electrode of the first sub pixel; and
a second pattern enclosing the first electrode of the second sub pixel and spaced apart from the first pattern,
wherein the display apparatus further includes:
a planarization layer disposed between the substrate and the first electrode, wherein an upper surface of the planarization layer is exposed by the first pattern and the second pattern.
